(19) United States
(12) Patent Application Publication
(10) Pub. No.: US 2005/0063894 A1
(43) Pub. Date: Mar. 24, 2005

(54) Dispersion management optical lithography crystals for below 160nm optical lithography & method thereof

(76) Inventor: Robert W. Sparrow, Sturbridge, MA (US)

Correspondence Address: CORNING INCORPORATED, SP-TI-3-1, CORNING, NY, 14831, US

(21) Appl. No.: 10/982,679

(22) Filed: Nov. 4, 2004

Related U.S. Application Data
(63) Continuation-in-part of application No. 09/991,399, filed on Nov. 20, 2001.

(51) Int. Cl. C01D 3/02; C30B 33/06

(52) U.S. Cl. 423/490; 117/1

(57) ABSTRACT

The present invention provides fluoride lens material crystals for VUV optical lithography systems and processes. The invention provides a fluoride optical lithography crystal for utilization in below 200 nm photolithography methods, for example 157 nm optical microlithography elements which manipulate below 193 nm optical lithography photons. The invention particularly pertains to mixed metal fluoride crystals; for example crystals comprised of an alkali metal fluoride and an alkaline earth metal fluoride; crystals comprised of a first alkaline metal fluoride and a second alkaline earth metal fluoride in which the two metals are different; and crystals comprised of an alkaline earth metal fluoride and lanthanum fluoride.

### CROSS-REFERENCE TO RELATED APPLICATIONS

This is a continuation-in-part of U.S. patent application Ser. No. 09/991,399 filed on Nov. 20, 2001, the content of which is relied upon and incorporated herein by reference in its entirety, and the benefit of priority under 35 U.S.C. § 120 is hereby claimed.

### BACKGROUND OF THE INVENTION

1. Field of the Invention

The present invention relates generally to optical lithography, and particularly to optical microlithography crystals for use in optical photolithography systems utilizing vacuum ultraviolet light (VUV) wavelengths below 200 nm, preferably below 193 nm, preferably below 175 nm, more preferably below 164 nm, such as VUV projection lithography refractive systems utilizing wavelengths in the 157 nm region. The present invention relates to below 200 nm, and below 160 nm optical lithography systems that utilize optical fluoride crystals to minimize dispersion of 157 nm light.

2. Technical Background

Semiconductor chips such as microprocessors and DRAM's are manufactured using a technology called “Optical Lithography”. An optical lithographic tool incorporates an illuminating lens system for illuminating a patterned mask, a light source and a projection lens system for creating an image of the mask pattern onto the silicon substrate.

The performance of semiconductors have been improved by reducing the feature sizes. This in turn has required improvement in the resolution of the optical lithographic tools. In general, the resolution of the transferred pattern is directly proportional to the numerical aperture of the lens system and inversely proportional to the wavelength of the illuminating light. In the early 1980's the wavelength of light used was 436 nm from the g-line of a mercury lamp. Subsequently the wavelength was reduced to 365 nm (I-line of mercury lamp) and currently the wavelength used in production is 248 nm obtained from the emission of a KrF laser. The next generation of lithography tools will change the light source to that of an ArF laser emitting at 193 nm. The natural progression for optical lithography would be to change the light source to that of a fluoride laser emitting at 157 nm. For each wavelength different materials are required to fabricate lenses. At 248 nm the optical material is fused silica. For 193 nm systems there will be a combination of fused silica and calcium fluoride lenses. At 157 nm fused silica does not transmit the laser radiation. At present the preferred material for use at 157 nm by the optical lithography semiconductor industry is pure calcium fluoride crystal.

Projection optical photolithography systems that utilize the vacuum ultraviolet wavelengths of light below 200 nm and also at or below 193 nm provide benefits in terms of achieving smaller feature dimensions. For example, systems that utilize vacuum ultraviolet wavelengths in the 157 nm wavelength region have the potential of improving integrated circuits with smaller feature sizes. Current optical lithography systems used by the semiconductor industry in the manufacture of integrated circuits have progressed but the commercial use and adoption of vacuum ultraviolet wavelengths below 200 nm, for example below 193 nm and below 157 nm, has been hindered by the transmission nature of such vacuum ultraviolet wavelengths in these lower regions, e.g., the 157 nm region, through optical materials. For the benefit of vacuum ultraviolet photolithography in the 157 nm region such as the emission spectrum VUV window of a F₂ excimer laser to be utilized in the manufacturing of integrated circuits there is a need for optical lithography crystals that have beneficial optical properties below 164 nm and at 157 nm.

The present invention overcomes problems in the prior art and provides a fluoride optical lithography crystal for use below 200 nm that can be used to improve the manufacturing of integrated circuits with vacuum ultraviolet wavelengths. The commercial use and adoption of below 160 nm UV in high volume mass production of integrated circuits hinges on the availability of economically manufacturable optical fluoride crystals with high quality optical performance.

Fluoride crystals for use below 200 nm, and below 160-nm must have high internal transmission at the use wavelength (>98%/cm), high index of refraction homogeneity (<2 ppm) and low residual stress birefringence (<3 nm/cm). Stress birefringence is a consequence of the manufacturing process and can be minimized through careful annealing of the crystal. This distinction becomes clear when addressing a property called “spatial dispersion”. Spatial dispersion is a property that is described as the presence of birefringence that is dependent on the direction of light propagation. In crystals such as Ge, Si and GaP, however, there is such a dependence that is found to exhibit 1/λ² variation with wavelength (Optical Anisotropy of Silicon Single Crystals, by J. Pastrnak and K. Vedam, PHYSICAL REVIEW B, VOLUME 3, NUMBER 8, Apr. 15, 1971, p. 2567-2571; COMPUTATIONAL SOLID STATE PHYSICS, by Peter Y. Yu and Manuel Cardona, Plenum Press, N.Y., edited by F. Herman, 1972; Spatial Dispersion In The Dielectric Constant of GaAs, by Peter Y. Yu and Manuel Cardona, SOLID STATE COMMUNICATIONS, VOLUME 9, NUMBER 16, Aug. 15, 1971, pp.1421-1424). Spatial dispersion, is absent from the dielectric response of a cubic crystal in the limit in which the wavelength of light, λ, is much larger than the spacing between atoms. As the wavelength becomes smaller, such as at VUV wavelengths below 160 mm, additional terms in the dielectric response are no longer negligible. In a cubic crystal, inversion symmetry of the crystal structure only allows the first nonzero contribution to occur at order 1/λ² and not order 1/λ. There is a mathematical description of dielectric response and crystal symmetry that uses tensors and their transformations to describe how dielectric response (including spatial dispersion) can depend on the direction of light propagation. Dielectric response is described using a rank 2 tensor, denoted εᵢⱼ. The lowest order effects of spatial dispersion can be described by a rank 4 tensor, here denoted αᵢⱼₖₗ, from the relation

$${ɛ}_{ij} ( \vec{q} ) = {ɛ}_{ij} ( \vec{q} = 0 ) + {\sum }_{kl}^{} {α}_{ijkl} {q}_{k} {q}_{l} .$$

Here the symbol \vec{q} represents the wavevector of light; it points in the direction of light propagation and its magnitude is

$$\frac{2 π}{λ} .$$

The equation shows that the long-wavelength or \vec{q}=0 part of the dielectric tensor gets corrected by the sum of elements of the αᵢⱼₖₗ tensor times the x-, y-, or z-components of the wavevector. (The sum on k and l is a sum over cartesian directions x, y, and z.) This correction term represents the source of spatial dispersion. In the absence of this term, a cubic crystal would have a completely isotropic dielectric tensor εᵢⱼ and hence no spatial dispersion. Of the possible 3×3×3×3=81 terms in the αᵢⱼₖₗ tensor, only 3 are nonzero and distinct in a cubic crystal with m3m symmetry, such as zincblende or fluorite structure crystals. It is known that rank 4 tensors have 3 tensor invariants. In fully isotropic systems such as glass, the tensor αᵢⱼₖₗ only have 2 independent nonzero elements, and obeys the relation
(α₁₁₁₁−α₁₁₂₂)/2−α₁₂₁₂=0.

The independent nonzero elements can be taken as α₁₁₁₁ and α₁₁₂₂. In a cubic system with m3m symmetry, the relation above need not be satisfied, and there are 3 independent nonzero elements of αᵢⱼₖₗ. These may be taken as α₁₁₁₁, α₁₁₂₂, and α₁₂₁₂. Since the first two tensor invariants are present in isotropic glasses, they cannot impart any anisotropy. Thus all anisotropy from spatial dispersion in cubic crystals is associated with the relation
(α₁₁₁₁−α₁₁₂₂)/2−α₁₂₁₂≠0.

The value of this combination of tensor elements in a cubic system sets the scale for all anisotropic optical properties associated with spatial dispersion. These constants themselves depend on the wavelength of light with a variation such as that of index dispersion, and. much less variation with wavelength than the explicit 1/λ².

Pure calcium fluoride for UV lithography systems exhibits spatial dispersion. Spatial dispersion is an inherent optical dispersion characteristic of the crystal and as such cannot be reduced by processing such as annealing. Stress-induced birefringence and spatial dispersion birefringence can be distinguished by their respective wavelength dependences. The variation of spatial dispersion with wavelength is very strong compared with the variation in stress-induced birefringence with wavelength, with spatial dispersion having 1/λ² dependence.

Birefringence, whether it is derived from stress or the spatial properties of the crystal, can have a detrimental effect on high performance optical systems. The formation of multiple images is a major concern. Phase front distortion also presents problems both in terms of imaging and metrology. Given the wavelength dependence of spatial dispersion and the bandwidth of the lasers, dispersion becomes an important issue. It is thus of importance to minimize the amount of birefringence in a material for use in high performance optical imaging systems. Stress-related birefringence can be minimized with annealing by controlled heating and slow cooling that allows the crystal to reach thermal equilibrium over a long period of time, while spatial dispersion is an inherent property that must be addressed in a different manner. An approach is to prepare mixed crystals that have minimized spatial dispersion; such as an isotropic fluoride crystal that contains more than one metal cation that can minimize dispersions, including spatial dispersion, and have optical characteristics different from pure calcium fluoride, such as refractive index and dispersions that are different from pure calcium fluoride. This approach recognizes that optical characteristics such as spatial birefringence, refractive index, and dispersion, of a given fluoride crystal is determined by the cations that make up the fluoride crystal.

The present invention overcomes problems in the prior art and provides a means for economically manufacturing high quality crystals that can be used to improve the manufacturing of integrated circuits with ultraviolet wavelengths below 200 nm. It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

### SUMMARY OF THE INVENTION

The present invention is directed to a below 200 nm optical lithography fluoride crystal for minimizing below 200 nm dispersion in optical lithography systems utilizing below 200 nm wavelengths such as 193 nm and 157 nm. Preferably the fluoride crystal has a refractive index wavelength dispersion dn/dλ<−0.003 at 157 nm and is comprised of an alkaline earth metal fluorides in combination with an alkali metal fluoride, a different alkaline earth metal fluoride or lanthanum fluoride.

One aspect of the present invention is a below 160 nm optical lithography fluoride crystal for minimizing below 160 nm dispersion in optical lithography systems utilizing below 160 nm wavelengths such as 157 nm. Preferably the fluoride crystal has a refractive index wavelength dispersion dn/dλ<−0.003 at 157 nm and is comprised of barium fluoride.

In another aspect, the present invention includes a dispersion management optical lithography crystal. The dispersion management crystal is an isotropic fluoride crystal, preferably comprised of barium. Preferably the barium fluoride crystal of the invention has a 157.6299 nm refractive index wavelength dispersion dn/dλ less than −0.003 and a 157.6299 nm refractive index n>1.56.

In a further aspect, the present invention includes a below 160 nm optical lithography method which comprises providing a below 160 nm optical lithography illumination laser, providing a calcium fluoride crystal optical element, providing a barium fluoride crystal optical element having dispersion characteristics different from calcium fluoride, and transmitting the below 160 nm optical lithography light through the calcium fluoride optical element and the barium fluoride optical element to form an improved optical lithography pattern with managed minimized dispersion with the barium fluoride crystal optical element dispersion characteristics correcting and compensating for the dispersion characteristics of the calcium fluoride.

In another aspect, the present invention includes a method of making a dispersion managing optical lithography element. The method includes providing a dispersion correction material fluoride source material, melting the correction fluoride source material to form a precrystalline fluoride melt, solidifying the fluoride melt into a dispersion correction fluoride crystal and annealing the fluoride crystal to provide an isotropic fluoride dispersion correction crystal having dispersion characteristics different from calcium fluoride, preferably with a 157 nm refractive index wavelength dispersion characteristic dn/dλ<−0.003, and forming the crystal into a below 160 nm dispersion managing optical lithography element.

Wherein reducing the wavelength of the illuminating light for lithography processes is necessary to achieve higher resolution, the illuminating light laser emission has a finite bandwidth. To achieve the resolution required at the 100 nm node, the optical lithography tool manufacturer using an all refractive optical design can either use a very highly line narrowed laser (to less than 2 pm) or can use two optical materials which have dispersion properties that compensate for the bandwidth of the laser.

In a preferred embodiment the invention includes providing isotropic optical lithography crystalline materials for dispersion correction for below 200 nm VUV lithography in general but especially in the regions of 193 and 157 nm to enable refractive lenses to be constructed to make use of the light from a fluoride excimer laser that has not been line narrowed to below 2 pm. The invention includes a range of fluoride crystalline materials that provide benefits to 157 nm optical lithography. In the preferred embodiment the dispersion managing optical lithography crystal is utilized in conjunction with a 157 nm optical lithography illumination laser with a bandwidth not less than 0.2 picometers (“pm”).

The present invention relates to optical lithography, and particularly to optical microlithography crystals for use in optical photolithography systems utilizing vacuum ultraviolet light (VUV) wavelengths below 200 nm, below 193 nm, preferably below 175 nm, more preferably below 164 nm, such as VUV projection lithography refractive systems utilizing wavelengths in the 157 nm region. The present invention relates to below 160 nm optical lithography systems that utilize optical fluoride crystals to minimize dispersion of 157 nm light, with the optical fluoride crystals correcting wavelength and spatial dispersion of the 157 nm lithography light to minimize abberations in the lithography system with improved focus and resolution. The optical fluoride crystals of the invention have different dispersion characteristics (including different spatial dispersion and different chromatic dispersion characteristics) than that of pure calcium fluoride crystals and provide improvements over the shortfalls of those of calcium fluoride crystals utilized in 157 nm VUV projection lithography refractive lithography systems.

The invention includes a mixed fluoride crystal that exhibits minimal spatial dispersion. The mixed crystal has an isotropic structure with a first metal cation and a second metal cation.

The invention includes a fluoride crystal having a minimized amount of spatial dispersion. The mixed fluoride crystal has an isotropic fluoride crystal molecular structure and is comprised of a plurality of first metal cations and a plurality of second metal cations. The mixture of the different metal cations provide optical characteristic that are beneficial for dispersion below 160 nm optical lithography and utilization in 157 nm wavelength projection lithography refractive systems for transmitting 157 nm wavelengths with improved resolution and focus. Preferably the appropriate combination of metal cations in the fluoride crystal yields a crystal exhibiting minimized spatial dispersion and color correction for the below 160 nm optical lithography system.

Additional features and advantages of the invention will be set forth in the detailed description which follows, and in part will be readily apparent to those skilled in the art from the description or recognized by practicing the invention as described herein, including the detailed description which follows and the claims.

It is to be understood that both the foregoing general description and the following detailed description are merely exemplary of the invention, and are intended to provide an overview of framework for understanding the nature and character of the invention as it is claimed.

### DESCRIPTION OF THE DRAWINGS

FIG. 1 illustrates a dispersion managed optical lithography system/method with dispersion management optical lithography crystal elements in accordance with the invention.

### DETAILED DESCRIPTION OF THE PREFERRED EMBODIMENTS

As used herein, the alkali metals will be represented by the symbol “A”, alkaline earth metals will be represented by the symbol “M” (or “M1” and “M2” when two alkaline earth metal are present in a single formulation, and lanthanum will be represented by the symbol “L”.

The crystals described herein are generally useful in belowm 200 nm lithography systems. Although certain examples in the specification may refer to a specific wavelength such as “below 160 nm”, and measurements may have been made a a specific belo 200 nm wavelength such as 157 nm, this is to be understood as also meaning below 200 nm use.

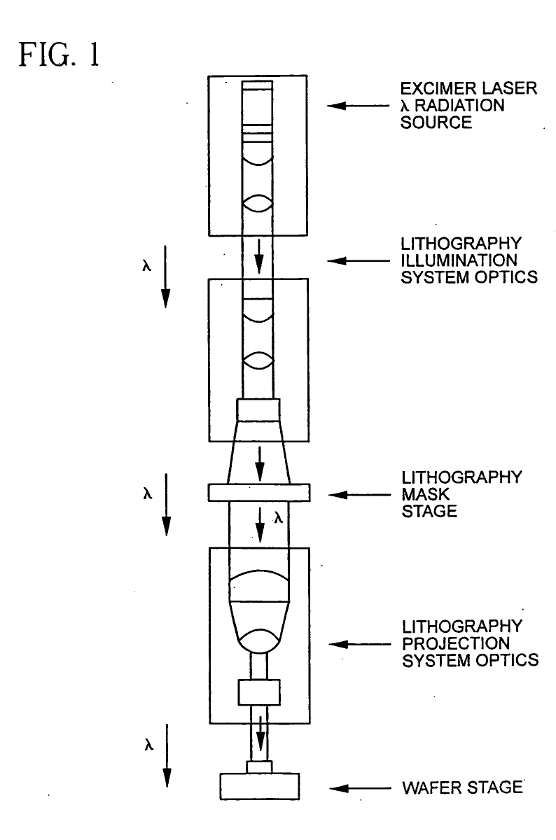

The invention includes a below 200 nm photolithographic method, such as shown in FIG. 1. The method includes providing a below 200 nm radiation source. Preferably the radiation source is a F₂ excimer laser which produces a laser emission wavelength λ of about 157 nm or an ArF laser source that produces a laser emission wavelength of about 193 nm.

The refractive index of a material varies with the wavelength of energy passing through it and this is called the dispersion of the material. The wavelength energy of the light includes the polarization states and the direction of the light thus the refractive index of the material is dependent on the polarity and direction of the energy passing through it. Hence if light passing through a lens system, constructed of one optical material, has a range of energy characteristics including wavelength and polarity direction thereof then the light would be brought to a range of different focus thus dispersed and reducing resolution and having aberrations. This effect can be overcome by using an optical material with different dispersion characteristics. To be of use as a dispersion correction material, there are specific criteria that have to be met, namely the material must transmit at the wavelength of operation, it must be isotropic and must have optimum dispersion characteristics. Applying the criteria of 157 nm transmission and of being isotropic, the following materials can be used as dispersion correction materials.

I. Materials Based on Alkali Metal Fluorides:

Lithium fluoride, sodium fluoride, potassium fluoride, and materials of the formula: AMF₃ in which A is either Li, Na or K and M is either Ca, Sr, Ba or Mg. Examples of such materials include but are not limited to: KMgF₃, KSrF₃, KBaF₃, KCaF₃, LiMgF₃, LiSrF₃, LiBaF₃, LiCaF₃, NaMgF₃, NaSrF₃, NaBaF₃, and NaCaF₃.

II. Materials Based on Alkaline Earth Metal Fluorides:

Calcium fluoride, barium fluoride and strontium fluoride. Each of these materials can be combined with the other to form a mixed crystal of the formula (M1)ₓ(M2)₁₋ₓF₂ in which M1 is different from M2 and M1 is either Ba, Ca or Sr and M2 is either Ba, Ca or Sr, and x is an quantity between 0 and 1; preferably, x is greater than 0 and less than 1 (0<x<1). Non-limiting examples are Ba_{0.5}Sr _{0.5}F₂ in which x=0.5 and Ba_{0.25}Sr_{0.75}F₂, in which x=0.75. When x=0, the materials are CaF₂, BaF₂, SrF₂

III. Alkaline Earth-Lanthanum Based Mixed Metal Fluorides

Materials based on mixed crystals of the formula M₁₋ₓLₓF₂₊ₓ, in which M is either Ca, Ba or Sr and L is lanthanum. In such materials the structure of the crystal is isotropic up to x values of 0.3. Examples of this formula include but are not limited to Ca_{0.72}La_{0.28}F_{2.28} which x=0.28 or Ba_{0.74}La_{0.26}F_{2.26} in which x=0.26 or of the type Sr_{0.79}La_{0.21}F_{2.21} in which x=0.21. Accordingly, x has a value in the range of greater than 0 up to 0.3.

Each of the above materials I, II and III can be manufactured using a technique known as the “Stockbarger” or “Bridgman” technique of crystal growth. This process comprises loading the powder of the material to be grown into a container known as a crucible. The crucible which usually is made of high purity graphite is positioned on a moveable support structure within a heater with sufficient power to raise the temperature to a level above the melting point of the material to be grown. After assembling the heater system around the crucible, the system is closed with a bell jar and evacuated using a combination of vacuum pumps. After a vacuum exceeding 10⁻⁵ Torr has been achieved, power is applied to the heater and is continually raised until a preset level has been achieved. This preset level of power is defined by melt trial runs. After a period of several hours at the melt power, the moveable support structure is activated and the crucible is made to slowly descend in the furnace. As the tip of the crucible descends, it cools and the molten material begins to freeze. By continuing the descent there is progressive solidification until all the melt is frozen. At this point, the power to the furnace is reduced to below the melt power, the crucible is raised back into the heater, allowed to reach thermal equilibrium over a period of several hours and then allowed to cool to room temperature by slowly reducing the power to the heaters. This allows the crystal to reach thermal equilibrium over a long period of time with controlled heating/cooling anneals the crystal and minimizes stress induced birefringence since stress can be formed and remain in a crystal that has not been allowed to reach thermal equilibrium. Once at room temperature, the vacuum is released, the bell jar removed followed by the heaters and the crystal can be removed from the crucible.

Although the Bridgman or Stockbarger method of crystal growth is the usual method of growing crystals of fluoride based materials, it is not the only method available. Techniques such as the Czochralski, Kyropoulos or Stober methods can also be utilized.

The size and shape of the disks resulting from these materials are variable, e.g. for lenses: 118-250 mm in diameter by 30-50 mm in thickness. The disks are ground in a conventional manner to lenses of about the same dimensions and having the desired curvature. The lenses have a general application, for example, whenever dispersion correction is required. The lenses can then be incorporated in a wide variety of optical systems, e.g. lasers including but limited to the 193 nm and 157 nm systems, spectrography systems, microscopes and telescopes.

The invention includes a below 200 nm transmitting optical crystal such as a below 160 nm transmitting optical fluoride crystal for use with a below 160 nm lithography laser having a bandwidth of at least 0.2 pm with the inventive optical crystal having dispersion characteristics different from calcium fluoride. The optical lithography fluordie crystal is preferably comprised of an isotropic fluoride crystal containing barium and which has a 157 nm transmission greater than 85% and a refractive index wavelength dispersion dn/dλ<−0.003 at 157 nm. Preferably the fluoride crystal has a 157 nm, refractive index wavelength dispersion dn/dλ<−0.004, and more preferably <−0.0043. Preferably the fluoride crystal has a 157 nm refractive index index n>1.56. More preferably n>1.6, and most preferably n>0.64. Preferably the fluoride crystal has a 157 nm refractive index temperature coefficient dn/dt>8×10⁻⁶/° C., and more preferably dn/dt≧8.5×10⁻⁶/° C. In a preferred embodiment the optical lithography fluoride crystal has a large dimension diameter >100 mm and a thickness >30 mm, and more preferably a diameter in the range of about 118 to 250 nm and a thickness in the range of about 30 to 50 mm. When utilized with a broadband width illumination source such as an F₂ excimer laser with a bandwidth of at least 0.5 pm, said barium fluoride crystal comprises a bandwidth dispersion managing optical element. In preferred embodiments the barium fluoride optical lithography crystal has a sodium contamination content <10 ppm by weight, more preferably <5 ppm by weight, and most preferably <1 ppm. In preferred embodiments the barium fluoride optical lithography crystal has a total rare earth contaminant content of less than 1 ppm by weight. Preferably the barium fluoride optical lithography crystal has a total oxygen contaminant content of less than 50 ppm by weight, and more preferably <20 ppm. Such low contaminant levels provide beneficial optical characteristics, and preferably the crystal has a 157 nm transmission >86%, and more preferably ≧8%.

In a further aspect the invention includes a below 160 nm dispersion management optical lithography crystal. The dispersion management optical lithography crystal comprises an isotropic fluoride crystal having a 157.6299 nm refractive index wavelength dispersion dn/dλ<−0.003 and a 157.6299 nm refractive index n>1.56. Preferably the dispersion management crystal's dn/dλ<−0.004, and more preferably dn/dλ<−0.0043. Preferably the crystal's refractive index n>1.6. Preferably the crystal is comprised of barium fluoride and has dispersion characteristics different from pure CaF₂.

In a further aspect the invention includes a below 200 nm optical lithography method such as a 160 nm optical lithography method which includes providing a below 160 nm optical lithography illumination laser, providing a calcium fluoride crystal optical element, and providing a barium fluoride crystal optical element having below 160 nm optical dispersion characteristics which correct for the calcium fluoride crystal optical element and compensate for the dispersions of the calcium fluoride crystal. Preferably the barium fluoride crystal optical element has a refractive index wavelength dispersion dn/dλ which is <−0.003. The method includes transmitting below 160 nm optical lithography light through the calcium fluoride optical element and the barium fluoride optical element to form an optical lithography pattern, with minimized dispersion preferably with feature dimensions <100 nm. Providing the barium fluoride crystal optical element preferably includes loading a crystal feedstock containing barium fluoride into a container, melting the feedstock to form a precrystalline melt containing barium fluoride, and progressively freezing the melt into a crystal comprised of barium fluoride. The method of making preferably further includes heating the fluoride crystal and slowly thermal equilibrium cooling the crystal and forming the crystal containing barium fluoride into an optical element. Preferably the illumination laser has a bandwidth ≧0.5 pm, and preferably ≧1 pm. In an embodiment the invention includes the method of making a dispersion managing optical lithography element. The method includes providing a barium fluoride source material, melting the barium fluoride source material to form a precrystalline barium fluoride melt, solidifying the barium fluoride melt into a barium fluoride crystal, and annealing the barium fluoride crystal to provide an isotropic barium fluoride crystal with a 157 nm refractive index wavelength dispersion dn/dλ<−0.003. The method preferably includes providing a contaminant removing fluoride scavenger and melting the scavenger with the barium fluoride source material to remove contaminants. Preferably the scavenger is lead fluoride.

### EXAMPLE

Barium fluoride optical lithography crystal samples were produced. 157 nm range refractive index measurements were made on a produced crystal. 157 nm range transmission exposures were made on a produced crystal.

Crystals were grown in high purity graphite crucible containers. High purity barium fluoride powder was loaded into the crucible. The loaded crucible was positioned on a movable support structure within a crystal growing heater device with sufficient power to raise the temperature to a temperature above 1280° C. The barium fluoride powder was melted above 1280° C. into a precrystalline barium fluoride melt, then the crucible was lowered through a 1280° C. containing thermal gradient to progressively freeze solidify the melt into a crystalline form. The formed crystal was then annealled by heating to a temperature below 1280° C. and then slowly cooling to allow the barium fluoride crystal to reach thermal equilibrium and reduce stress and birefringence of the crystal. Such formed barium fluoride crystal samples were then analyzed. A 157 nm transmission laser durability sample showed an external transmission of 86%. A 157 nm absolute refractive index sample showed a 157 nm dispersion at 20° C. of dn/dλ (157.6299)=−0.004376±0.000004 nm⁻¹ with the absolute refractive index at the 157 nm wavelength of 157.6299, n(λ=157.6299)=1.656690±0.000006, and also the refractive index temperature coefficient about 20° C. was found to be dn/dT (approx. 20° C., 1 atmosphere N₂)=10.6 (±0.5)×10⁻⁶/° C. and dn/dT (approx. 20° C., vacuum)=8.6(±0.5)×10⁻⁶/° C.

The invention includes a below 200 nm optical lithography method, for example, a below 160 nm optical lithography method comprised of providing a below 160 nm optical lithography illumination laser, providing a calcium fluoride crystal optical element, providing a barium fluoride crystal optical element, said barium fluoride crystal element having a below 160 nm dispersion different from said calcium fluoride crystal, and transmitting below 160 nm optical lithography light through said calcium fluoride optical element and said barium fluoride optical element to form an optical lithography pattern. Preferably the barium fluoride crystal element has a below 160 nm chromatic dispersion different from said calcium fluoride crystal below 160 nm chromatic dispersion. Preferably the barium fluoride crystal element has a below 160 nm spatial dispersion different from said calcium fluoride crystal below 160 nm spatial dispersion. Preferably the barium fluoride crystal element has a below 160 nm wavelength dependent dispersion different from said calcium fluoride crystal below 160 nm wavelength dependent dispersion.

The invention includes a below 200 nm optical lithography method, for example, a below 160 nm optical lithography method comprised of providing a below 160 nm optical lithography illumination laser, providing a calcium fluoride crystal optical element, providing a dispersion management fluoride crystal optical element, said dispersion management fluoride crystal element having a dispersion different from said calcium fluoride crystal, and transmitting below 160 nm optical lithography light through said calcium fluoride optical element and said dispersion management fluoride crystal optical element to form an optical lithography pattern with said dispersion management fluoride crystal optical element dispersion correcting said calcium fluoride crystal dispersion. The providing a dispersion management fluoride crystal optical element preferably includes loading a dispersion management fluoride correction material crystal feedstock into a container, melting said fluoride crystal feedstock to form a precrystalline fluoride melt, progressively freezing said fluoride melt into a dispersion correction management fluoride crystal, heating said fluoride crystal and thermal equilibrium cooling said dispersion management crystal, and forming said dispersion management fluoride crystal into an dispersion management optical element.

The invention includes a below 200 nm optical lithography method, for example, a below 160 nm optical lithography method comprised of providing a below 160 run optical lithography illumination laser, providing a dispersion management fluoride crystal optical element, said dispersion management fluoride crystal element having a below 160 nm dispersion different from a calcium fluoride crystal, and transmitting below 160 nm optical lithography light through said dispersion management fluoride crystal optical element to form an optical lithography pattern. Preferably the dispersion management fluoride crystal element has a below 160 run chromatic dispersion different from calcium fluoride crystal below 160 nm chromatic dispersion. Preferably the dispersion management fluoride crystal element has a below 160 nm spatial dispersion different from calcium fluoride crystal below 160 nm spatial dispersion. Preferably the dispersion management fluoride crystal element has a below 160 nm wavelength dependent dispersion different from a calcium fluoride crystal below 160 nm wavelength dependent dispersion.

The invention includes a method of making a dispersion managing optical lithography element. The method includes providing a source material containing barium fluoride, melting said source material containing barium fluoride to form a precrystalline melt containing barium fluoride, solidifying said melt containing barium fluoride into an isotropic fluoride crystal containing barium fluoride, and annealing said crystal containing barium fluoride to provide an isotropic fluoride crystal containing barium fluoride.

The invention includes a method of making a dispersion managing optical lithography crystal for correcting calcium fluoride at below 200 nm, for example, at 193 nm and at 157 nm. The method includes providing a dispersion management correction fluoride material, melting said dispersion correction fluoride material to form a precrystalline fluoride dispersion correction material melt, solidifying said fluoride dispersion correction material melt into a dispersion correction material fluoride crystal, and annealing said dispersion correction material fluoride crystal to provide an isotropic dispersion correction material fluoride crystal with a 157 nm transmission >80%.

In an embodiment the invention includes providing an alkali metal-alkaline earth metal fluoride mixture, said mixture comprised of metals A and M wherein A is an alkali metal chosen from the alkali metal group consisting of Li, Na, and K, and M is an alkaline earth metal chosen from the alkaline earth metal group consisting of Ca, Sr, Ba and Mg.

The alkali metal alkaline earth metal fluoride mixture is loaded into the crucible and melted to form a precrystalline alkali metal alkaline earth metal fluoride mixture melt which is then progressively solidified into a alkali metal alkaline earth metal mixed crystal of formula AMF3, where A is the alkali metal chosen from the alkali metal group consisting of Li, Na, and K, and M is the alkaline earth metal chosen from the alkaline earth metal group consisting of Ca, Sr, Ba and Mg.

In another embodiment the invention includes providing an alkaline earth metal fluoride mixture, said mixture comprised of (M1)F₂ and (M2)F₂ where M1 is a first alkaline earth metal chosen from the alkaline earth metal group consisting of Ca, Sr, and Ba, and M2 is a second alkaline earth metal chosen from the alkaline earth metal group consisting of Ca, Sr, and Ba, and M2 is an alkaline earth metal different from M1.

The alkaline earth metal fluoride mixture is loaded into a crucible and melted to form a precrystalline alkaline earth metal fluoride mixture melt, which is then progressively solidified into an alkaline earth metal mixed crystal of (M1)ₓ(M2)₁₋ₓF₂ where M1 is the first alkaline earth metal chosen from the alkaline earth metal group consisting of Ca, Sr, and Ba, and M2 is the second alkaline earth metal chosen from the alkaline earth metal group consisting of Ca, Sr, and Ba, and x is between 0 and 1, preferably, x is greater than 0 and less than 1, and M1 is different from M2.

In another embodiment the invention includes providing an alkaline earth metal lanthanum fluoride mixture, said mixture comprised of lanthanum and an alkaline earth metal M chosen from the alkaline earth metal group consisting of Ca, Sr, and Ba, with the mixture being M₁₋ₓLaₓF₂₊ₓ with x being no greater than 0.3 and L=lanthanum. The mixture is loaded into a crucible and melted to form a precrystalline alkaline earth metal lanthanum fluoride mixture melt, which is then progressively solidified into an alkaline earth metal lanthanum mixed crystal of M₁₋ₓLaₓF₂₊ₓ with x no greater than 0.3

It will be apparent to those skilled in the art that various modifications and variations can be made to the present invention without departing from the spirit and scope of the invention. Thus, it is intended that the present invention cover the modifications and variations of this invention provided they come within the scope of the appended claims and their equivalents.

1. A dispersion management optical lithography crystal for managing dispersion below 200 nm, said crystal comprising a mixed metal fluoride crystal of an alkaline metal fluoride, the first metal fluoride, and a second metal fluoride selected from the group consisting of:
(a) an alkali metal fluoride,
(b) a second alkaline earth metal fluoride, wherein said second alkaline earth metal fluoride is different from said first alkaline earth metal fluoride, and
(c) lanthanum fluoride; and
said dispersion management optical lithography crystal further comprises a fluoride crystal having a 157 nm transmission >85% and a refractive index wavelength dispersion dn/dλ<−0.003 at 157 nm.

2. The lithography crystal according to claim 1(a), wherein said mixed metal fluoride crystal is of formula AMF₃, where A is an alkali metal selected from the group consisting of Li, K and K, and M is an alkaline earth metal selected from the group consisting of Mg, Ca, Ba and Sr.

3. The lithography crystal according to claims 2, wherein the alkali metal is Li and the alkaline earth metal is selected from the group consisting of Ca, Ba and Sr.

4. The lithography crystal according to claim 2, wherein the alkali metal is Na and the alkaline earth metal is selected from the group consisting of Ca, Ba and Sr.

5. The lithography crystal according to claim 1(b), wherein said mixed metal crystal is of formula (M1)ₓ(M2)₁₋ₓF₂; M1 is a first alkaline earth metal selected from the group consisting of Mg, Ca, Ba and Sr; M2 is a second alkaline earth metal selected from the group consisting of Mg, Ca, Ba and Sr; x is a quantity between 0 and 1; and M1 and M2 are different.

6. The mixed metal crystal according to claim 5, wherein M1 is Sr and M2 is selected from the group consisting of Ca and Ba.

7. The mixed metal crystal according to claim 5, wherein M1 is Sr, M2 is Ba, and x is in the range of 0.5 to 0.75.

8. The mixed metal crystal according to claim 5, wherein M1 is Sr, M2 is Ca, and x is in the range of 0.5 to 0.75.

9. The mixed metal crystal according to claim 5, wherein M1 is Ca, M2 is Ba, and x is in the range of 0.5 to 0.75.

10. The mixed metal crystal according to claim 5, wherein M1 is Ca, M2 is Ba, and x is in the range of 0.5 to 0.75.

11. The lithography crystal according to claim 1(c), wherein said mixed metal crystal is of formula M₁₋ₓLₓF₂₊ₓ, M is an alkaline earth metal fluoride selected from the group consisting of Ca, Ba and Sr; L is lanthanum fluoride, and x is no greater than 0.3

12. The lithography crystal according to claim 11, wherein x is in the range of 0.21 to 0.28.

13. The lithography crystal according to claim 11, wherein M is Ca and x=0.28.

14. The lithography crystal according to claim 11, wherein M is Ba and x=0.26.

15. The lithography crystal according to claim 11, wherein M is Sr and x=0.21

16. A dispersion management optical lithography crystal comprised of an isotropic metal fluoride crystal, said metal fluoride crystal having a 157.6299 nm refractive index wavelength dispersion dn/dλ<−0.003 and a 157.6299 nm refractive index n>1.56.

17. The dispersion management crystal according to claim 15, wherein said crystal has a measured external 157 nm transmission ≧85%.
